(19) United States
(12) Patent Application Publication
(10) Pub. No.: US 2007/0004091 A1
(43) Pub. Date: Jan. 4, 2007

(54) Semiconductor device and manufacturing method thereof

(75) Inventors: Michiaki Tamagawa, Aizuwakamatsu (JP); Masaharu Minamizawa, Aizuwakamatsu (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/320,737

(22) Filed: Dec. 30, 2005

(30) Foreign Application Priority Data
Jun. 30, 2005 (JP) 2005-190859

(51) Int. Cl. H01L 21/00

(52) U.S. Cl. 438/122

(57) ABSTRACT

A semiconductor device having high reliability and excellent heat radiation and a method for manufacturing the device at low coat. A semiconductor element and a cover as a heat radiation member are bonded through a solder-containing carbon member having a structure that outside solder layers are formed on a surface of a solder-containing carbon sintered body formed by impregnating a carbon sintered body with solder. By using the sintered body for a junction between the semiconductor element and the cover, thermal stress during heat generation in the semiconductor element can be relieved while securing high heat radiation. By impregnating the sintered body with inexpensive solder, the sintered body and the outside solder layers can be tightly bonded. Through the outside solder layers, the semiconductor element and the cover can be tightly bonded. Thus, the semiconductor device having high reliability and excellent heat radiation can be realized at low cost.

### CROSS-REFERENCE TO RELATED APPLICATIONS

This application is based upon and claims the benefits of priority from the prior Japanese Patent Application No. 2005-190859, filed on Jun. 30, 2005, the entire contents of which are incorporated herein by reference.

### BACKGROUND OF THE INVENTION

1. Field of the Invention

The present invention relates to a semiconductor device and a method for manufacturing the semiconductor device, and more particularly to a semiconductor device having a semiconductor element and a heat radiation member which radiates heat generated by the semiconductor element. The invention also pertains to a method for manufacturing the semiconductor device.

2. Description of the Related Art

In recent years, a high integration and speeding-up tendency of semiconductor elements incorporated into a semiconductor device is progressing. Along with the progress, the elements have a tendency to increase in a heating value during the operation. However, the increase in the heating value acts as a factor capable of mechanically or electrically obstructing conduction and therefore, is likely to cause reduction in reliability of the semiconductor device. Accordingly, heat generated by the semiconductor elements must be effectively radiated outside the semiconductor device. In order to enhance heat radiation, some semiconductor devices having an appropriate heat radiation member are also conventionally proposed.

For example, there is proposed a semiconductor device in which a semiconductor element is flip-chip mounted on an electrical circuit substrate and then, a heat radiation member composed of ceramics or metals is bonded to the semiconductor element through a layer composed of metals such as solder, cupper (Cu) or gold (Au) (See, e.g., Japanese Unexamined Patent Publication No. 2001-127218). Thus, an attempt of improving the heat radiation of the semiconductor device is being made by bonding the semiconductor element and the heat radiation member using a metal having excellent thermal conductivity.

Further, in recent years, an attempt of using for a semiconductor device a carbon material such as a sintered body mainly composed of carbon is also being performed in terms of a high thermal conductivity, electric conduction property, thermal expansion characteristics and mechanical strength (See, e.g., Japanese Unexamined Patent Publication No. 06-321649).

However, when using a heat radiation member for a semiconductor device to enhance the heat radiation, the following problems occur.

For example, in the case of bonding a semiconductor element and a heat radiation member by a layer composed of a metal such as solder, since a difference in a thermal expansion coefficient between the metal layer and the semiconductor element mainly composed of semiconductor materials such as silicon (Si) is relatively large, a defect occurs in the metal layer or the semiconductor element is destroyed due to stress concentration during heating generation. As a result, securement of high reliability is difficult in terms of performance or heat radiation. Also in the case of using a semiconductor element having a larger size or in the case where a difference in the thermal expansion coefficient between a heat radiation member and a metal layer is relatively large, securement of high reliability is difficult.

Further, in the case of bonding a semiconductor element and a heat radiation member using silver (Ag) paste in place of a metal such as solder, the silver (Ag) paste has a function of relieving thermal stress because it is relatively soft. However, the silver paste is lower than a metal such as solder in thermal conductivity. As a result, a problem remains in terms of the heat radiation.

Further, in the case of using a sintered body mainly composed of carbon (referred to as a “carbon sintered body”) as a member for bonding a semiconductor element and a heat radiation member, the carbon sintered body is expected to exert a relieving function of thermal stress or a high thermal conduction function. However, even if the carbon sintered body is singly provided between the semiconductor element and the heat radiation member, it is difficult for the sintered body to bond both of them. Therefore, a surface of the sintered body must be metalized. Examples of the metalizing process include a method for sputtering a carbon sintered body surface with a metal to form on the surface thereof a metal layer or a method for forming on the surface of the sintered body an appropriate layer composed of a solder metal for brazing a semiconductor element and a heat radiation member.

However, according to the method for sputtering the carbon sintered body surface with a metal to form on the surface thereof a metal layer, the metal is only accumulated on the surface of the carbon sintered body. Therefore, bond strength between the carbon sintered body and the metal is relatively low. As a result, this method is likely to cause reduction in reliability of the semiconductor device. Further, the method for forming a solder metal layer on a surface of a carbon sintered body is effective in making a film of the metal layer thicker or in improving bond strength between the carbon sintered body and the metal. On the other hand, the method has a problem that since the solder metal is relatively expensive, a manufacturing cost of the semiconductor device is increased.

### SUMMARY OF THE INVENTION

In view of the foregoing, it is an object of the present invention to provide a semiconductor device which can be formed at low cost and has high reliability and excellent heat radiation.

Another object of the present invention is to provide a method for manufacturing the semiconductor device.

To accomplish the above objects, according to one aspect of the present invention, there is provided a semiconductor device having a semiconductor element and a heat radiation member which radiates heat generated by the semiconductor device. In the semiconductor device, the semiconductor element and the heat radiation member are bonded through a metal-containing carbon member formed by using a carbon material having incorporated thereinto a metal.

According to another aspect of the present invention, there is provided a method for manufacturing a semiconductor device having a semiconductor element and a heat radiation member which radiates heat generated by the semiconductor element. The method comprises the steps of: forming a metal-containing carbon member using a carbon material having incorporated thereinto a metal, disposing the metal-containing carbon member on the semiconductor element mounted on a substrate, disposing the heat radiation member on the metal-containing carbon member disposed on the semiconductor element, and bonding the semiconductor element and the heat radiation member through the metal-containing carbon member.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a schematic sectional view showing an essential part of a semiconductor device according to a first embodiment of the present invention.

FIG. 2 shows one example of a formation flow of a solder-containing carbon member.

FIG. 3 shows another example of a formation flow of a solder-containing carbon member.

FIG. 4 shows one example of a formation flow of a semiconductor device according to a first embodiment of the present invention.

FIG. 5 is a schematic sectional view showing an essential part of a conventional semiconductor device.

FIG. 6 is a schematic sectional view showing an essential part of a semiconductor device according to a second embodiment of the present invention.

### DESCRIPTION OF THE PREFERRED EMBODIMENTS

By taking as an example a case of using solder as a metal for a metal-containing carbon member, preferred embodiments of the present invention will be described in detail below with reference to the accompanying drawings. A term “containing” used for a metal such as solder herein means a case where a certain amount of metal is contained. This term excludes a case where only a small amount of metal is contained as in a metal in the form of impurities.

A first embodiment will be described.

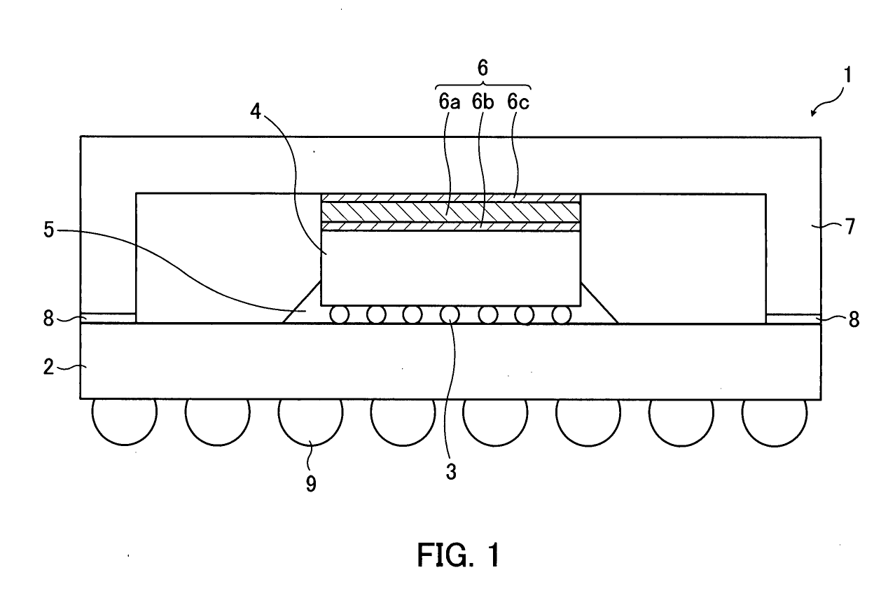

FIG. 1 is a schematic sectional view showing an essential part of a semiconductor device according to a first embodiment of the present invention.

A semiconductor device 1 according to the first embodiment has a structure that a semiconductor element 4 is flip-chip mounted on an electrical circuit substrate 2 through solder bumps 3. Between the electrical circuit substrate 2 and the semiconductor element 4, an underfill material 5 is filled to enhance connection strength therebetween. To the semiconductor element 4, a solder-containing carbon member 6 constituted by using porous carbon materials such as a carbon sintered body having incorporated thereinto a predetermined amount of solder is bonded to a surface side opposite to a mounting surface on the electrical circuit substrae 2. Further, in the solder-containing carbon material 6, a box-type cover 7 is bonded to a surface side opposite to the semiconductor element 4. The cover 7 plays a role in protecting the semiconductor element 4 from external shock or pollution as well as plays a roll as a heat radiation member which radiates heat generated during operation of the semiconductor element 4 to the outside of the semiconductor device 1. Herein, the cover 7 is bonded to the solder-containing carbon member 6 as well as an open end of the cover 7 is bonded to the electrical circuit substrate 2 using a resin 8. Further, solder balls 9 used for the mounting on another electrical circuit substrate are fitted on the electrical circuit substrae 2.

Herein, a ceramic substrate or a resin substrate can be used for the electrical circuit substrae 2. Eutectic solder (Sn/37Pb) or tin-silver solder (Sn/3Ag) can be used for the solder bumps 3 or the solder balls 9. The number added to the front of an atomic symbol of the solder notation represents the content of the element (hereinafter, the same as above). A variety of semiconductor elements can be used for the semiconductor element 4. In general, a semiconductor element having a size up to about 25 mm is frequently used. One or two or more semiconductor elements 4 as described above are mounted on the electrical circuit substrae 2. FIG. 1 shows a case where only one semiconductor element 4 is mounted on the electrical circuit substrae 2. An epoxy thermosetting resin can be used for the underfill material 5 or the resin 8. In accordance with a mode (a size or a heating value) of the semiconductor element 4, metals or ceramics as well as carbon materials such as carbon nanotubes are used for the cover 7 in primary consideration of thermal conductivity of the cover 7.

Further, the solder-containing carbon member 6 which is provided between the semiconductor element 4 and the cover 7 has a structure that solder layers (referred to as an “outside solder layer”) 6b and 6c are formed on each surface side of a solder-containing carbon sintered body 6a formed by incorporating a predetermined amount of solder into a carbon sintered body such as a graphite plate. In the semiconductor device 1, the semiconductor element 4 is bonded to the outside solder layer 6b formed on one surface side of the solder-containing carbon member 6. Further, the cover 7 is bonded to the outside solder layer 6c formed on the other surface side of the solder-containing carbon member 6.

Each of the thicknesses of the solder-containing carbon sintered body 6a and outside solder layers 6b and 6c constituting the solder-containing carbon member 6 is set, for example, up to about 300 μm. The thicknesses of the solder-containing carbon sintered body 6a and the outside solder layers 6b and 6c are appropriately set in accordance with a mode of the semiconductor element 4 used.

For solder incorporated into the solder-containing carbon sintered body 6a, solder mainly composed of Sn such as Sn/37Pb or so-called low melting point solder which contains bismuth (Bi) can be used in addition to Sn/3Ag or Sn/2.5Ag/0.5Cu. A composition of the solder used for the solder-containing carbon sintered body 6a is appropriately set in accordance with a melting temperature of the solder or a mode of the semiconductor element 4 used. The solder content of the solder-containing carbon sintered body 6a depends on the composition of the solder incorporated. The content is, for example, from 5 to 20% by weight, preferably from 8 to 12% by weight. As the solder content of the solder-containing carbon sintered body 6a is higher, an elastic modulus thereof is likely to more decrease, as compared with a case where the solder content thereof is lower. Therefore, the sintered body 6a having higher solder content is effective, particularly, when being used for a low elastic product.

For solder used for the outside solder layers 6b and 6c, solder mainly composed of Sn such as Sn/3Ag, Sn/2.5Ag/0.5Cu, Sn/37Pb or low melting point solder containing Bi can be used in the same manner as in the solder-containing carbon sintered body 6a.

The composition of solder contained in the solder-containing carbon sintered body 6a and that used for the outside solder layers 6b and 6c may be the same or different from each other.

As described above, in the semiconductor device 1 according to the first embodiment, the semiconductor element 4 and the cover 7 are bonded through the solder-containing carbon member 6 having the solder-containing carbon sintered body 6a and the outside solder layers 6b and 6c. When directly bonding between the solder-containing carbon member 6 and the semiconductor element 4 as well as between the solder-containing carbon member 6 and the cover 7, the outside solder layers 6b and 6c which are formed outside the solder-containing carbon sintered body 6a are used.

By thus using the solder-containing carbon member 6 formed by using a carbon sintered body for a junction between the semiconductor element 4 and the cover 7, the carbon member 6 relieves thermal stress due to heat generation in the semiconductor element 4 as well as effectively transmits heat generated by the semiconductor element 4 to a heat radiation member. As a result, stress concentration can be effectively avoided as compared with a conventional case of using a metal layer for the junction between the semiconductor element 4 and the cover 7. Further, heat can be effectively radiated as compared with a case of using Ag paste for the junction therebetween.

Further, the solder-containing carbon member 6 has a structure that the outside solder layers 6b and 6c are formed on each surface of the solder-containing carbon sintered body 6a formed by incorporating solder into the carbon sintered body. Therefore, the outside solder layers 6b and 6c are tightly bonded to the solder-containing carbon sintered body 6a. Accordingly, the outside solder layers 6b and 6c are prevented from being peeled off from the surface of the solder-containing carbon sintered body 6a during using the semiconductor device 1, so that high heat radiation can be secured. Further, solder mainly composed of relatively inexpensive Sn can be used for the solder-containing carbon member 6. Therefore, as compared with a conventional case of forming a layer of a relatively expensive solder metal on the surface of the carbon sintered body, the solder-containing carbon member 6 can be formed at low cost, which can contribute to reduction in cost of the semiconductor device 1.

Further, since the solder-containing carbon member 6 has a structure that the outside solder layers 6b and 6c are formed on each surface of the solder-containing carbon sintered body 6a, high bond strength can be obtained between the semiconductor element 4 and the cover 7. Particularly, in the case of using conventional Ag paste for the junction, since this material has a relatively high hygroscopic property, peeling-off of a bonded interface may occur when performing the subsequent reflow in a moisture state. On the contrary, since the solder-containing carbon member 6 has a structure that the outside solder layers 6b and 6c are formed on each surface of the solder-containing carbon sintered body 6a, the carbon member 6 has a low hygroscopic property. As a result, the peeling-off of the bonded interface can be prevented from occurring.

Next, a formation method of the solder-containing carbon member 6 will be described.

As described above, the carbon member 6 has a structure that the solder layers are further formed on each surface of the solder-containing carbon sintered body.

Herein, the carbon sintered body used for this solder-containing carbon member 6 can be formed using a conventionally known method. For example, there is heretofore proposed a method for forming a flake-like -porous carbon material by impregnating pulp raw materials with a thermosetting resin and then press forming and carbonizing the materials under a non-oxidizing atmosphere (see, e.g., Japanese Patent No. 3008095). In addition to this method, any method may be used as long as a porous carbon sintered body can be formed.

However, in forming the carbon sintered body, the solder content of the solder-containing carbon sintered body 6a is largely affected by the porosity of the carbon sintered body as described below. Therefore, the sintered body must be formed with this point in view.

In order to incorporate solder into the thus obtained carbon sintered body, there can be used, for example, a method of impregnating a porous carbon sintered body with molten solder.

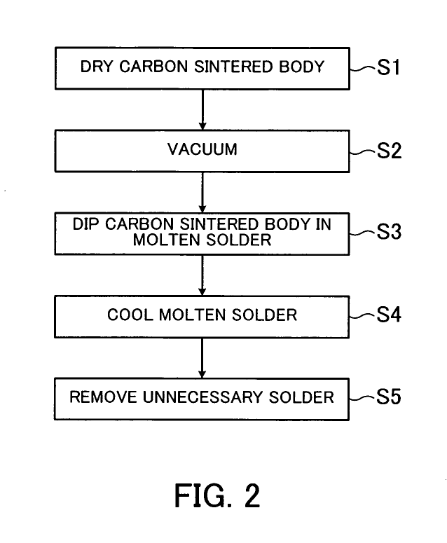

FIG. 2 shows one example of a formation flow of the solder-containing carbon member.

The solder-containing carbon member 6 is formed by the following procedures. First, the carbon sintered body is sufficiently dried to remove moisture within fine pores of the carbon sintered body (step S1). After the drying, the dried carbon sintered body is moved to a predetermined chamber and vacuuming within the chamber is performed to exhaust a gas and moisture inside the chamber (step S2).

Further, while keeping a vacuum atmosphere, the carbon sintered body is dipped in molten solder at a temperature of the melting point or more for a given length of time (step S3). As a result, the molten solder is allowed to penetrate into fine pores of the carbon sintered body. The amount of the solder which penetrates into fine pores of the carbon sintered body mainly depends on the porosity of the carbon sintered body. That is, as the porosity of the carbon sintered body is higher, the amount of the penetrating molten solder more increases. On the other hand, as the porosity of the carbon sintered body is lower, the amount thereof more decreases. The solder content of the finally obtained solder-containing carbon sintered body 6a is almost determined by the amount of the molten solder which penetrates into fine pores of the carbon sintered body.

After dipping the carbon sintered body in the molten solder for a given length of time, the molten solder is cooled (step S4). At this time, in the carbon sintered body, a fine pore inside thereof is impregnated with solder as well as solder with a fixed thickness is adhered to a surface thereof according to the composition or melting temperature of the solder.

After the cooling, unnecessary solder is removed from among the solder adhered to the surface of the carbon sintered body impregnated with the solder (step SS). On this occasion, the solder adhered to the carbon sintered body surface is allowed to remain with a constant thickness and solder other than the remaining solder is removed. As a result, there can be obtained the solder-containing carbon member 6 having a structure that the remaining portion is used for the outside solder layers 6b and 6c formed on the surface of the solder-containing carbon sintered body 6a.

When thus forming the solder-containing carbon member 6 according to the procedures as shown in steps S1 to S5, formation of the solder-containing carbon member 6 and that of the outside solder layers 6b and 6c can be simultaneously performed.

Further, in step S5 described above, the whole solder adhered to the carbon sintered body surface (till the carbon sintered body is exposed) may be removed. In this case, there is accordingly obtained the solder-containing carbon sintered body 6a having a structure that the outside solder layers 6b and 6c are not formed yet on each surface of the sintered body 6a.

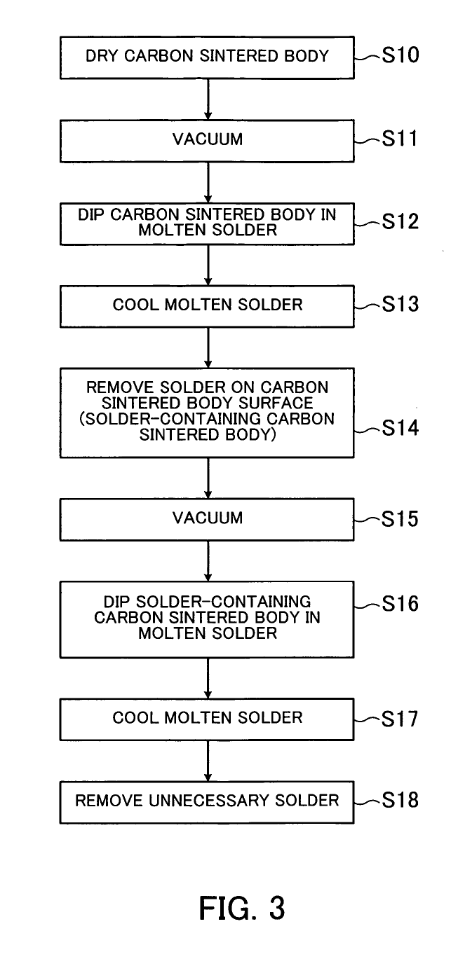

FIG. 3 shows another example of a formation flow of the solder-containing carbon member.

Herein, the solder-containing carbon member 6 is formed by the following procedures. Drying of the carbon sintered body (step S10), vacuuming (step S11), dipping of the carbon sintered body in molten solder (step S12) and cooling of the molten solder (step S13) are first performed in the same manner as in the formation flow shown in FIG. 2 above. Further, solder adhered to the surface of the carbon sintered body impregnated with solder is removed (step S14). Thus, the solder-containing carbon sintered body 6a is obtained.

Thereafter, in the same manner as in the above, vacuuming is first performed (step S15). While keeping a vacuum atmosphere, the solder-containing carbon sintered body 6a is dipped in the molten solder at a temperature of the melting point or more (step S16). On this occasion, solder having a melting point lower than that of the solder with which the solder-containing carbon sintered body 6a is impregnated is desirably used. This is because the solder with which the solder-containing carbon sintered body 6a is impregnated is melted in this stage to diffuse into the molten solder, and therefore, an effect of impregnating the carbon sintered body with solder may be reduced.

Further, after cooling the molten solder (step S17), solder adhered to the surface of the solder-containing carbon sintered body 6a is allowed to remain with a constant thickness and unnecessary solder other than the remaining solder is removed (step S18). Thus, the outside solder layers 6b and 6c are formed on the surface of the solder-containing carbon sintered body 6a.

When thus forming the solder-containing carbon member 6 according to the procedures as shown in steps S10 to S18, formation of the solder-containing carbon sintered body 6a and that of the outside solder layers 6b and 6c are separately performed. As a result, the composition of the solder with which the solder-containing carbon sintered body 6a is impregnated and that of the solder which constitutes the outside solder layers 6b and 6c can be changed from each other.

When using the above-described methods as exemplified in FIGS. 2 and 3 above, the solder-containing carbon member 6 can be formed.

Next, a formation method of the semiconductor device 1 using the solder-containing carbon member 6 will be described.

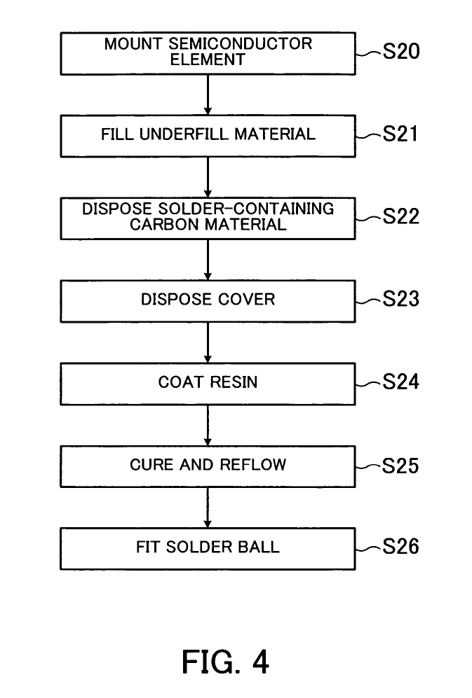

FIG. 4 shows one example of a formation flow of the semiconductor device according to the first embodiment of the present invention.

The semiconductor device 1 is formed by the following procedures. First, the semiconductor element 4 is flip-chip mounted on the electrical circuit substrate 2 through the solder bumps 3, and the semiconductor element 4 and the electrical circuit substrate 2 are connected to each other (step S20). Further, the underfill material 5 is filled between the semiconductor element 4 and the electrical circuit substrate 2 (step S21).

Next, on the semiconductor element 4, the solder-containing carbon member 6 is disposed (step S22) and thereon, the cover 7 is further disposed (step S23). Between an open end of the cover 7 and the electrical circuit substrate 2, the resin 8 is coated (step S24).

Thereafter, curing and reflowing are performed (step S25). As a result, solder used for the outside solder layers 6b and 6c formed on each surface of the solder-containing carbon member 6 is melted to allow bonding between the solder-containing carbon member 6 and the semiconductor element 4 as well as between the solder-containing carbon member 6 and the cover 7. Depending on the solder composition (or the melting point) used for the outside solder layers 6b and 6c, the bonding temperature is generally about from 130° C. to 250° C. Further, at this time, the cover 7 and the electrical circuit substrate 2 are also bonded together by curing of the resin 8.

Finally, the solder balls 9 are fitted on the electrical circuit substrate 2 (step S26). Thus, the semiconductor device 1 of FIG. 1 is completed.

Herein, a case of bonding the open end of the cover 7 and the electrical circuit substrate 2 using the resin 8 is described. However, the bonding between these parts is not necessarily required. In such a case, the above-described step S24 may be omitted.

Next, results of the comparison between the semiconductor device 1 and a conventional semiconductor device will be described. The conventional semiconductor device used herein has a structure that a semiconductor element and a cover are bonded using solder or Ag paste.

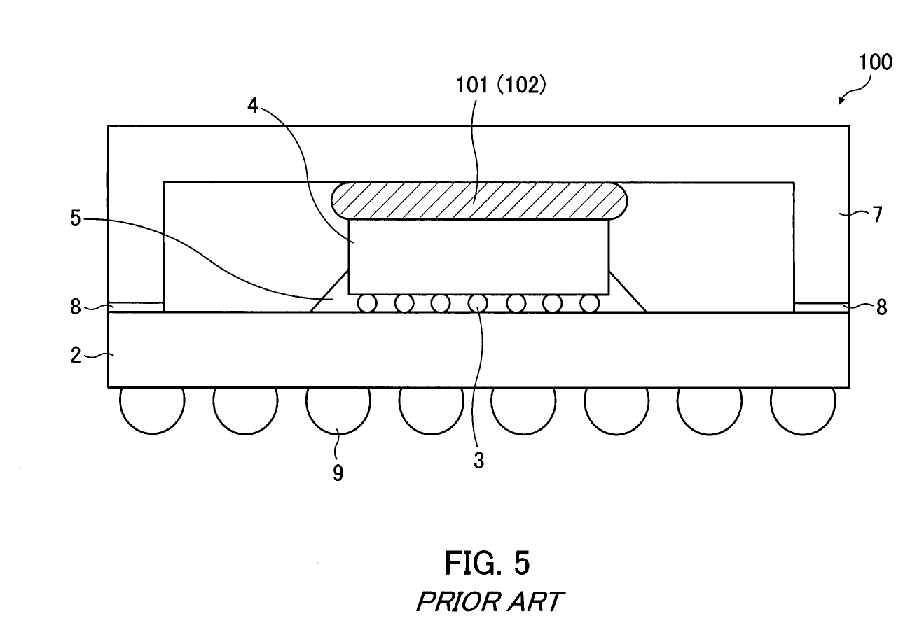

FIG. 5 is a schematic sectional view showing an essential part of the conventional semiconductor device. In FIG. 5, the same elements as those in FIG. 1 are indicated by the same reference numerals as in FIG. 1 and the detailed description is omitted.

A semiconductor device 100 shown in FIG. 5 has the same constitution as that of the semiconductor device 1 shown in the FIG. 1 except that the semiconductor element 4 and the cover 7 are bonded together through a solder layer 101 composed of Sn/37Pb or an Ag paste layer 102.

Relating to the solder layer 101 and Ag paste layer 102 used in the conventional semiconductor device 100 as well as relating to the solder-containing carbon member 6 used in the semiconductor device 1 shown in FIG. 1, herein, the solder-containing carbon member 6 formed by using Sn/3Ag solder for both of the inside and the outside, the thermal conductivity and elasticity modulus thereof are collectively shown in Table 1.

TABLE 1

| | Thermal Conductivity | Elasticity |
|---|---|---|
| | (W/mk) | Modulus (GPa) |
| Sn/37Pb | 50.7 | 32 |
| Ag Paste | 1 to 2 | 1 |
| Solder-Containing | 80 or more | 10 |
| Carbon Member | | |
| (Containing Sn/3Ag) | | |

As seen from Table 1, the thermal conductivity of Sn/37Pb is 50.7 W/m·K and the elasticity modulus thereof is 32 GPa. The thermal conductivity of Ag paste formed by kneading and curing a resin and an Ag filler is from 1 to 2 W/m·K and the elasticity modulus thereof is 1 GPa. The thermal conductivity of the solder-containing carbon member 6 is 80 W/m·K or more, and the elasticity modulus thereof is 10 GPa.

Each of the conventionally used Sn/37Pb and Ag paste has advantages and disadvantages. The Sn/37Pb solder has high thermal conductivity as a material used for a junction between the semiconductor element 4 and the cover 7. However, the Sn/37Pb solder has a high elasticity modulus and is a hard material in terms of stress, and therefore, stress concentration easily occurs. On the other hand, the Ag paste has a low elasticity modulus and is a soft material in terms of stress, and therefore, the stress concentration hardly occurs. However, the Ag paste has low thermal conductivity, and therefore, there remains a problem in heat radiation.

On the contrary, as a material used for a junction between the semiconductor element 4 and the cover 7, the solder-containing carbon sintered body 6a shows excellent characteristics in both of the thermal conductivity and the elasticity modulus. Therefore, even if the semiconductor device 1 is more increased in the heating value as compared with the conventional device, high heat radiation and reliability can be obtained.

Next, a second embodiment will be described.

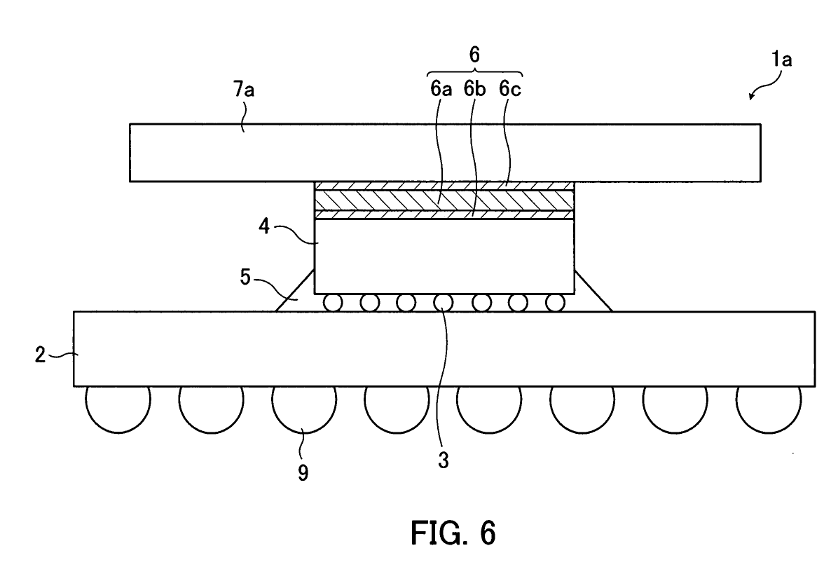

FIG. 6 is a schematic sectional view showing an essential part of a semiconductor device according to the second embodiment of the present invention. In FIG. 6, the same elements as those in FIG. 1 are indicated by the same reference numerals as in FIG. 1 and the detailed description is omitted.

A semiconductor device 1a shown in FIG. 6 differs from the semiconductor device 1 of the first embodiment in that a tabular cover 7a as a heat radiation member is bonded to the solder-containing carbon member 6 which is bonded to the semiconductor element 4 mounted on the electrical circuit substrae 2. Accordingly, bonding to the electrical circuit substrate 2 of the cover 7a using the resin 8 is unnecessary.

In accordance with a mode of the semiconductor element 4, metals, ceramics or carbon materials such as carbon nanotubes are used for the cover 7a in primary consideration of thermal conductivity of the cover 7a as in the cover 7 of the semiconductor device 1 of the first embodiment.

Another constitution of the semiconductor device 1a of the second embodiment and a formation method of the device 1a (including a formation method of the solder-containing carbon member 6) are the same as those in the semiconductor device 1 of the first embodiment. Also when using this tabular cover 7a, the same effect as in the semiconductor device 1 of the first embodiment can be obtained.

As described above, the semiconductor device 1 or 1a of the first or second embodiment is formed by bonding the semiconductor element 4 and the cover 7 or the semiconductor element 4 and the cover 7a through the solder-containing carbon member 6. Using a porous carbon sintered body having excellent properties in terms of thermal conductivity, thermal expansion characteristic and mechanical strength, the carbon member 6 is formed to have a structure that on each surface of the carbon sintered body 6a formed by impregnating the porous carbon sintered body with solder, the outside solder layers 6b and 6c are further provided. Therefore, in the solder-containing carbon member 6, the solder-containing carbon sintered body 6a and the outside solder layer 6b as well as the solder-containing carbon sintered body 6a and the outside solder layer 6c are tightly bonded using relatively inexpensive solder. At the same time, the solder-containing carbon member 6 is tightly bonded to both of the semiconductor element 4 and the cover 7 or both of the semiconductor element 4 and the cover 7a through the outside solder layers 6b and 6c. As a result, the stress concentration which may be generated during operations of the semiconductor element 4 can be effectively suppressed to prevent breakdown of the junction or the semiconductor element 4 as well as heat generated by the semiconductor element 4 can be effectively radiated. Accordingly, the semiconductor devices 1 and 1a having high reliability and excellent heat radiation can be realized at low cost.

The above description is made by taking as an example a case of using only solder for the metal-containing carbon member. Further, a metal other than solder, such as Cu or Au can also be used. In such a case, a carbon sintered body may be impregnated with Cu or Au to form on the surface thereof a metal layer composed of Cu or Au. Further, a carbon sintered body may be impregnated with solder to form on the surface thereof a metal layer composed of Cu or Au. Further, a carbon sintered body may be impregnated with Cu or Au to form on the surface thereof a solder layer. Also when using a metal other than solder, such as Cu or Au as described above, Cu or Au melted in an appropriate stage can be used in the same manner as in the above. In this case, the carbon sintered body may be impregnated with the melted Cu or Au or a layer may be formed on the surface of the carbon sintered body. When forming the metal layer composed of Cu or Au on the carbon sintered body surface, bonding is performed, for example, by thermocompression.

Further, the above-described solder composition is one example. Of course, the composition other than that exemplified above can also be used.

In the present invention, the semiconductor element and the heat radiation member are bonded through the metal-containing carbon member formed by using the carbon material having incorporated thereinto a metal. By thus using the carbon material for the junction between the semiconductor element and the heat radiation member, high heat radiation can be secured as well as stress concentration which may occur during heat generation in the semiconductor element can be avoided. Further, by incorporating the metal into the carbon material of the metal-containing carbon member, even if a layer composed of relatively inexpensive metal is formed on the surface of the carbon material, the carbon material and the metal layer can be tightly bonded as well as the semiconductor device and the heat radiation member can be tightly bonded. As a result, the semiconductor device having high reliability and excellent heat radiation can be realized at low cost.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor device, comprising:
a semiconductor element; and
a heat radiation member which radiates heat generated by the semiconductor element, wherein:
the semiconductor element and the heat radiation member are bonded through a metal-containing carbon member formed by using a carbon material having incorporated thereinto a metal.

2. The semiconductor device according to claim 1, wherein the metal is solder.

3. The semiconductor device according to claim 2, wherein the solder is mainly composed of Sn.

4. The semiconductor device according to claim 1, wherein:
the carbon material is a porous sintered body mainly composed of carbon.

5. The semiconductor device according to claim 1, wherein:
the metal-containing carbon member has a structure that a metal layer is formed on a surface of the carbon material having incorporated thereinto the metal.

6. The semiconductor device according to claim 5, wherein the metal layer is composed of solder.

7. The semiconductor device according to claim 5, wherein:
the semiconductor element and the heat radiation member are bonded to the metal-containing carbon member through the metal layer.

8. The semiconductor device according to claim 5, wherein:
the metal layer is composed of the same metal as that incorporated into the carbon material.

9. The semiconductor device according to claim 5, wherein:
the metal layer is composed of a metal different from that incorporated into the carbon material.

10. The semiconductor device according to claim 1, wherein:
the heat radiation member is composed of metal, ceramics or carbon.

11. The semiconductor device according to claim 1, wherein:
the semiconductor element is flip-chip mounted on an electrical circuit substrate.

12. The semiconductor device according to claim 11, wherein:
the electrical circuit substrate is a ceramics substrate or a resin substrate.

13. A method for manufacturing a semiconductor device having a semiconductor element and a heat radiation member which radiates heat generated by the semiconductor element, comprising the steps of:
forming a metal-containing carbon member using a carbon material having incorporated thereinto a metal;
disposing the metal-containing carbon member on the semiconductor element mounted on a substrate;
disposing the heat radiation member on the metal-containing carbon member disposed on the semiconductor element; and
bonding the semiconductor element and the heat radiation member through the metal-containing carbon member.

14. The method according to claim 13, wherein:
in the step of forming the metal-containing carbon member using the carbon material having incorporated thereinto the metal,
the carbon material is impregnated with the metal to form the carbon material having incorporated thereinto the metal; and
the metal-containing carbon member is formed using the carbon material having incorporated thereinto the metal.

15. The method according to claim 13, wherein the metal is solder.

16. The method according to claim 13, wherein:
in the step of forming the metal-containing carbon member using the carbon material having incorporated thereinto the metal,
a metal layer is formed on a surface of the carbon material having incorporated thereinto the metal to form the metal-containing carbon member.

17. The method according to claim 16, wherein the metal layer is composed of solder.

18. The method according to claim 16, wherein:
in forming the metal layer on the surface of the carbon material,
the metal layer is formed when forming the carbon material having incorporated thereinto the metal.

19. The method according to claim 16, wherein:
when forming the metal layer on the surface of the carbon material, the metal layer is formed after forming the carbon material having incorporated thereinto the metal.

20. A bonding member used for bonding between members, which has a structure that a metal layer is formed on a surface of a carbon material having incorporated thereinto a metal.
